(19) United States
(12) Patent Application Publication
(10) Pub. No.: US 2011/0019384 A1
(43) Pub. Date: Jan. 27, 2011

(54) PRINTED CIRCUIT BOARD ASSEMBLY

(75) Inventors: CHIEN-CHIH KAO, Tu-Cheng (TW); CHIA-WEN HUANG, Tu-Cheng (TW)

Correspondence Address: Altis Law Group, Inc.;ATTN: Steven Reiss, 288 SOUTH MAYO AVENUE, CITY OF INDUSTRY, CA, 91789, US

(73) Assignee: HON HAI PRECISION INDUSTRY CO., LTD., Tu-Cheng (TW)

(21) Appl. No.: 12/608,986

(22) Filed: Oct. 29, 2009

(30) Foreign Application Priority Data
Jul. 23, 2009 (CN) 200910304702.8

(51) Int. Cl. H05K 1/14; H05K 3/36

(52) U.S. Cl. 361/803; 29/830

(57) ABSTRACT

A printed circuit board assembly includes a central board and a peripheral board. The central board comprises a first connector, and is mounted with one or more of a CPU, memory, a north bridge chipset, and a south bridge chipset. The peripheral board is separated from the central board. The peripheral board comprises a second connector, and is mounted with a power source connector, a video chipset, an audio chipset, and a network card. The second connector is connected to the first connector to achieve communication between the central board and the peripheral board. The first connector and the second connector transmits one or more of DVP signals, VGA signals, SATA signals, LCD controlling signals, audio signals, speaker output signals, PCIE signals, LPC signals, PCI signals, video general input/output signals, USB signals between the central board and the peripheral board.

### BACKGROUND

1. Technical Field

The present disclosure related to circuit assemblies, and particularly to a printed circuit board assembly.

2. Description of Related Art

Electronic devices, such as personal computers, have a circuit board device that typically includes a printed circuit board, and a plurality of electronic components mounted on the printed circuit board and coupled electrically to each other by means of traces on the printed circuit board.

A conventional circuit board device includes a motherboard, a CPU, memory, a north bridge chipset, a south bridge chipset, a power source connector, a video chipset, an audio chipset, a network card, and so on. In the above components, the CPU, the memory, the north bridge chipset and the south bridge chipset are essential or central components of the circuit board device. Correspondingly, the power source connector, the video chipset, the audio chipset, and the network card are peripheral components of the circuit board device. Conventionally, the central components and the peripheral components are mounted on the same motherboard. Therefore, when only one component needs to be upgraded, the entire circuit board device has to be replaced with a new one, which results in higher costs.

Therefore, there is room for improvement within the art.

### BRIEF DESCRIPTION OF THE DRAWINGS

Many aspects of the embodiments can be better understood with references to the following drawings. The components in the drawings are not necessarily drawn to scale, the emphasis instead being placed upon clearly illustrating the principles of the embodiments. Moreover, in the drawings, like reference numerals designate corresponding parts throughout the several views.

FIG. 1 is a block view of a printed circuit board assembly.

FIG. 2 is a sketch view of a first connector of the printed circuit board assembly.

FIG. 3 is a sketch view of a second connector of the printed circuit board assembly.

### DETAILED DESCRIPTION

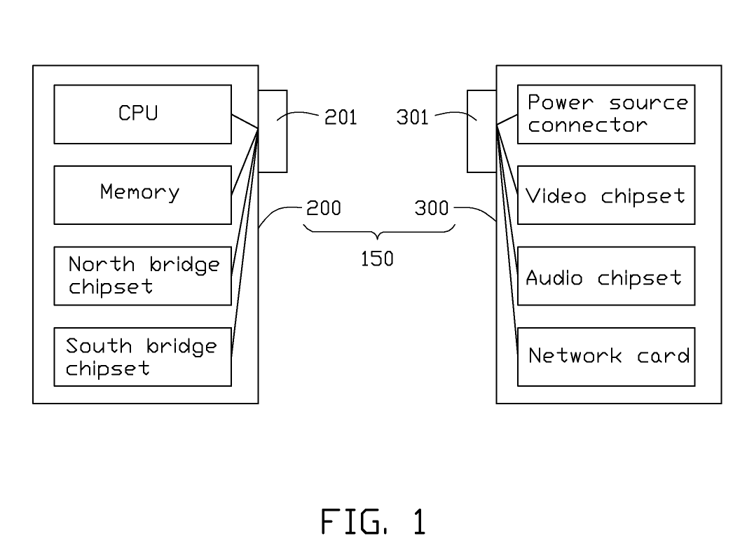

Referring to FIG. 1, a printed circuit board assembly 150 in accordance with an embodiment includes a central board 200 and a peripheral board 300.

The central board 200 is mounted with a CPU, memory, a north bridge chipset, a south bridge chipset, and a first connector 201.

The peripheral board 300 is mounted with a power source connector, a video chipset, an audio chipset, a network card, and a second connector 301 adapted to be connected to the first connector 201.

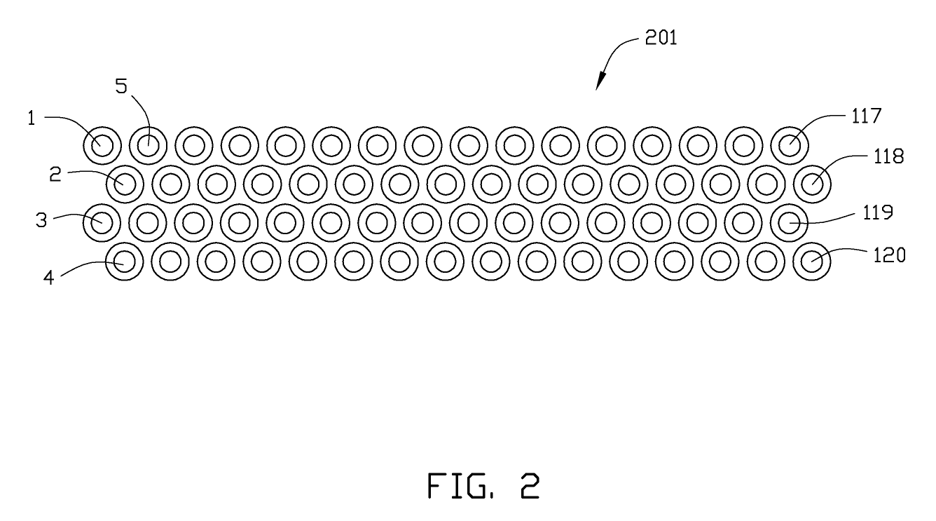

Referring to FIG. 2, the first connector 201 includes one hundred and twenty pins arranged in four rows and twenty lines. The pin which is located on the lowermost row and the leftmost line of the first connector 201 is pin 1. The pin which is located on the second upper row and the leftmost line of the first connector 201 is pin 2. Analogously, the pin which is located on the lowermost row and the rightmost line of the first connector 201 is pin 120.

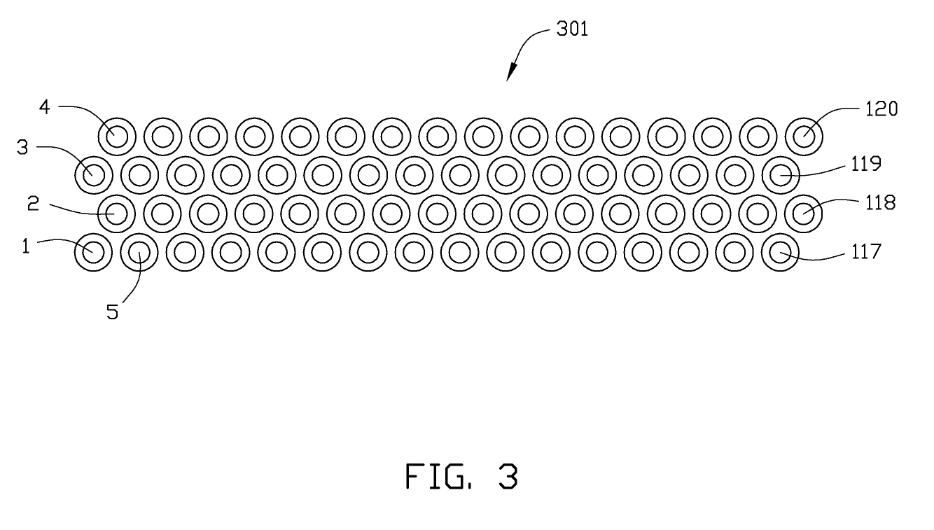

Referring to FIG. 3, the second connector 301 includes one hundred and twenty pads corresponding to the pins of the first connector 201. The pads are laid in four rows and twenty lines. The pad which is located on the lowermost row and the leftmost line of the second connector 301 is pad 1 and so on corresponding to the pins of the first connector 201, so that the corresponding pads of the second connector 301 are capable of connecting to the corresponding pins of the first connector 201, for example, the pin 1 of the first connector 201 being configured to couple with the pad 1 of the second connector 301.

The below table shows descriptions of the pins of the first connector 201.

| Pin | name | Description |
|---|---|---|
| 1 | DVPCLK | Clock signal of digital video port (DVP), one of the DVP |
| | | standard signals |
| 2 | GND | Ground |
| 3 | AR | VGA Red, one of the VGA standard signals |
| 4 | AB | VGA Blue, one of the VGA standard signals |
| 5 | INTERLOCK# | connector inter-lock, checking the connection between the first |
| | | connector 201 and the second connector 301 |
| 6 | GND | Ground |
| 7 | AG | VGA Green, one of the VGA standard signals |
| 8 | GND | Ground |
| 9 | HSYNC | VGA horizontal synchronous signal, one of the VGA standard |
| | | signals |
| 10 | VSYNC | VGA vertical synchronous signal, one of the VGA standard |
| | | signals |
| 11 | GND | Ground |
| 12 | SATA_RX+ | SATA receiving signal, one of the SATA standard signals |
| 13 | +3_3 V_AUX | +3.3 V auxiliary power signal |
| 14 | +3_3 V_AUX | +3.3 V auxiliary power signal |
| 15 | GND | Ground |
| 16 | SATA_RX− | SATA receiving signal, one of the SATA standard signals |
| 17 | +3_3 V_AUX | +3.3 V auxiliary power signal |
| 18 | GND | Ground |
| 19 | SATA_TX+ | SATA transmitting signal, one of the SATA standard signals |
| 20 | GND | Ground |
| 21 | DVPVS | DVP vertical synchronous signal, one of the DVP standard |
| | | signals |
| 22 | DVPHS | DVP horizontal synchronous signal, one of the DVP standard |
| | | signals |
| 23 | SATA_TX− | SATA transmitting signal, one of the SATA standard signals |
| 24 | GND | Ground |
| 25 | GND | Ground |
| 26 | DVPD9 | Digital Video Port Data 9, one of the DVP standard signals |
| 27 | GND | Ground |
| 28 | ENVDD | enable panel VDD power for LCD panel |
| 29 | DVPD0 | digital video port Data 0, one of the DVP standard signals |
| 30 | DVPD2 | digital Video port Data 2, one of the DVP standard signals |
| 31 | BLTCK | backlight PWM Clock Control |
| 32 | ENBLT1 | enable panel back light for LCD panel |
| 33 | DVPD3 | Digital Video Port Data 3, one of the DVP standard signals |
| 34 | DVPD4 | Digital Video Port Data 4, one of the DVP standard signals |
| 35 | VGA_SPD | VGA Serial Port (SMBus) Data, one of the VGA standard |
| | | signals |
| 36 | VGA_SPCK | VGA Serial Port (SMBus) Clock, one of the VGA standard |
| | | signals |
| 37 | DVPD5 | Digital Video Port Data 5, one of the DVP standard signals |
| 38 | DVPD6 | Digital Video Port Data 6, one of the DVP standard signals |
| 39 | TMDS_SPD | Digital Video Port Serial Port (SMBus) Clock, one of the DVP |
| | | standard signals |
| 40 | TMDS_SPCK | Digital Video Port Serial Port (SMBus) Data, one of the DVP |
| | | standard signals |
| 41 | DVPD7 | Digital Video Port Data 7, one of the DVP standard signals |
| 42 | DVPD8 | Digital Video Port Data 8, one of the DVP standard signals |
| 43 | SDOUT | High Definition Audio Serial Data Output, one of the audio |
| | | standard signals |
| 44 | BIT_CLK | High Definition Audio Bit Clock, one of the audio standard |
| | | signals |
| 45 | DVPD1 | Digital Video Port Data 1, one of the DVP standard signals |
| 46 | DVPD10 | Digital Video Port Data 10, one of the DVP standard signals |
| 47 | SYNC | High Definition Audio Sync, one of the audio standard signals |
| 48 | SPKR | Speaker Out |
| 49 | DVPD11 | Digital Video Port Data 11, one of the DVP standard signals |
| 50 | DVPD12 | Digital Video Port Data 12, one of the DVP standard signals |
| 51 | AZSDIN0 | High Definition Audio Serial Data Input, one of the audio |
| | | standard signals |
| 52 | ACRST# | High Definition Audio Reset, one of the audio standard signals |
| 53 | DVPD13 | Digital Video Port Data 13, one of the DVP standard signals |
| 54 | DVPD14 | Digital Video Port Data 14, one of the DVP standard signals |
| 55 | GND | Ground |
| 56 | DVPDET | Digital Video Port Display Detect, one of the DVP standard |
| | | signals |
| 57 | DVPD15 | Digital Video Port Data 15, one of the DVP standard signals |
| 58 | GND | Ground |
| 59 | DVPTVFLD | Digital Video Port Data 17/TV Field Out, one of the DVP |
| | | standard signals |
| 60 | DVPDE | Digital Video Port Data Enable, one of the DVP standard signals |
| 61 | GND | Ground |
| 62 | PE1CLK− | PCIE IX Clock, one of the PCIE IX standard signals |
| 63 | GND | Ground |
| 64 | LPCFRAME# | LPC(Low Pin Count) Frame, one of the LPC standard signal |
| 65 | GND | Ground |
| 66 | PE1CLK+ | PCIE 1X Clock, one of the PCIE 1X standard signal |
| 67 | LPCDRQ0# | LPC DMA/Bus Master Request 0, one of the LPC standard |
| | | signal |
| 68 | LPCAD2 | LPC Address/Data 2, one of the PCIE 1X standard signal |
| 69 | PEX1TX− | PCIE 1X Data, one of the PCIE IX standard signal |
| 70 | GND | Ground |
| 71 | LPCAD1 | LPC Address/Data 1, one of the LPC standard signal |
| 72 | LPCAD3 | LPC Address/Data 3, one of the LPC standard signal |
| 73 | PEX1TX+ | PCIE 1X data, one of the PCIE IX standard signal |
| 74 | PEX1RX− | PCIE 1X Data, one of the PCIE IX standard signal |
| 75 | LPCAD0 | LPC Address/Data 0, one of the LPC standard signal |
| 76 | PCICLK | PCI Clock, one of the PCI standard signal |
| 77 | GND | Ground |
| 78 | PEX1RX+ | PCIE 1X Data, one of the PCIE 1X standard signal |
| 79 | GND | Ground |
| 80 | VGP_IO | Video GPIO, video general input/output port |
| 81 | GND | Ground |
| 82 | GND | Ground |
| 83 | USBOC_1# | USB Over Current Detection for Port 4, 5 |
| 84 | USBOC_2# | USB Over Current Detection for Port 2, 3 |
| 85 | USBPO− | USB Data, one of the USB standard signal |
| 86 | USBPO+ | USB Data, one of the USB standard signal |
| 87 | USBOC_0# | USB Over Current Detection for Port 0, 1 |
| 88 | PWRBTN# | Power Button |
| 89 | GND | Ground |
| 90 | USBP5+ | USB Data, one of the USB standard signal |
| 91 | PCIRST# | PCI Reset, one of the PCI standard signal |
| 92 | WAKE# | PCIE Wake, one of the PCIE standard signal |
| 93 | USBP5− | USB Data, one of the USB standard signal |
| 94 | GND | Ground |
| 95 | BASE_GPIO | General Purpose Input/Output |
| 96 | SUSB# | Suspend Plane B Control |
| 97 | USBP2− | USB Data, one of the USB standard signal |
| 98 | USBP2+ | USB Data, one of the USB standard signal |
| 99 | SUSC# | Suspend Plane C Control |
| 100 | BASE_PG | Base Power Good |
| 101 | GND | Ground |
| 102 | USBP4− | USB Data, one of the USB standard signal |
| 103 | +12 V_PG | +12 V Power Good |
| 104 | DEVID_3 | Device ID, Device ID_0~3 providing sixteen types for choosing |
| | | different input/output module |
| 105 | USBP4+ | USB Data, one of the USB standard signal |
| 106 | GND | Ground |
| 107 | DEVID_2 | Device ID, Device ID_0~3 providing sixteen types for choosing |
| | | different input/output module |
| 108 | DEVID_1_SDA | Device ID, Device ID 0~3 providing sixteen types for choosing |
| | | different input/output module |
| 109 | USBP3− | USB Data, one of the USB standard signal |
| 110 | USBP3+ | USB Data, one of the USB standard signal |
| 111 | DEVID_0_CLK | Device ID, Device ID_0~3 providing sixteen types for choosing |
| | | different input/output module |
| 112 | GND | Ground |
| 113 | GND | Ground |
| 114 | USBP1− | USB Data, one of the USB standard signal |
| 115 | +12 V | +12 V power signal |
| 116 | +12 V | +12 V power signal |
| 117 | USBP1+ | USB Data, one of the USB standard signal |
| 118 | INTERLOCK# | Connector Inter-Lock, checking the connection between the first |
| | | connector 201 and the second connector 301 |
| 119 | +12 V | +12 V power signal |
| 120 | +12 V | +12 V power signal |

In the above table, the pins 1, 21, 22, 26, 29, 30, 33, 34, 37, 38, 39, 40, 41, 42, 45, 46, 50, 53, 54, 56, 57, 59, and 60 transmit DVP signals. The pins 3, 4, 7, 9, 10, 35, and 36 transmit VGA signals. The pins 2, 6, 8, 11, 15, 18, 20, 24, 25, 27, 55, 58, 61, 63, 65, 70, 77, 79, 81, 82, 89, 94, 101, 106, 112, and 113 are connected to ground. The pins 12, 16, 19, and 23 transmit SATA signals. The pins 28, 31, and 32 transmit LCD controlling signals. The pins 43, 44, 47, 51, and 52 transmit audio signals. The pin 48 transmits Speaker Output signal. The pins 62, 66, 69, 73, 74, 78, and 92 transmit PCIE signals. The pins 64, 67, 68, 71, 72, and 75 transmit LPC signals. The pins 76 and 91 transmit PCI signal. The pin 80 transmits video general input/output signal. The pins 83, 84, 85, 86, 87, 90, 93, 97, 98, 102, 109, 110, 114, and 117 transmit USB signals. The pins 104, 107, 108, and 111 are used to choose different input/output module. The pins 5 and 118 are used to check the connection between the first connector 201 and the second connector 301. Other pins are used to provide power and other control signals.

The pads 1-120 of the second connector 301 transmit corresponding signals of the pins 1-120 of the first connector 201. Therefore, the central board 200 and peripheral board 300 can communicate with each other via the first connector 201 and the second connector 301. As such, when some component on the peripheral board 300 needs to be upgraded, the peripheral board 300 can be replaced with a new one, and the central board 200 can be maintained.

It is to be understood, however, that even though numerous characteristics and advantages of the embodiments have been set forth in the foregoing description, together with details of the structure and function of the embodiments, the disclosure is illustrative only, and changes may be made in detail, especially in matters of shape, size, and arrangement of parts within the principles of the present disclosure to the full extent indicated by the broad general meaning of the terms in which the appended claims are expressed.

What is claimed is:

1. A printed circuit board assembly, comprising:
a central board comprising a first connector, the central board mounted with one or more of a CPU, memory, a north bridge chipset, and a south bridge chipset; and
a peripheral board separate from the central board, the peripheral board comprising a second connector, the peripheral board mounted with one or more of a power source connector, a video chipset, an audio chipset, and a network card, the second connector connected to the first connector to achieve communication between the central board and the peripheral board, the first connector and the second connector transmitting one or more of DVP signals, VGA signals, SATA signals, LCD controlling signals, audio signals, speaker output signals, PCIE signals, LPC signals, PCI signals, video general input/output signals, USB signals between the central board and the peripheral board.

2. The printed circuit board assembly of claim 1, wherein the first connector comprises one hundred and twenty pins, which are arranged in four rows and twenty lines; the second connector comprises one hundred and twenty pins corresponding to the pins of the first connector.

3. The printed circuit board assembly of claim 2, wherein a pin which is located on the lowermost row and the leftmost line of the first connector is pin 1; a pin which is located on the second upper row and the leftmost line of the first connector is pin 2; analogously, a pin which is located on the lowermost row and the rightmost line of the first connector is pin 120.

4. The printed circuit board assembly of claim 2, wherein the pins 1, 21, 22, 26, 29, 30, 33, 34, 37, 38, 39, 40, 41, 42, 45, 46, 50, 53, 54, 56, 57, 59, and 60 of the first connector transmit DVP signals; the pins 3, 4, 7, 9, 10, 35, and 36 of the first connector transmit VGA signals; the pin 80 of the first connector transmits video general input/output signal.

5. The printed circuit board assembly of claim 2, wherein the pins 64, 67, 68, 71, 72, and 75 of the first connector transmit LPC signals.

6. The printed circuit board assembly of claim 2, wherein the pins 62, 66, 69, 73, 74, 78, and 92 of the first connector transmit PCIE signals; the pins 76 and 91 of the first connector transmit PCI signals; the pins 12, 16, 19, and 23 of the first connector transmit SATA signal; the pins 83, 84, 85, 86, 87, 90, 93, 97, 98, 102, 109, 110, 114, and 117 of the first connector transmit USB signals.

7. The printed circuit board assembly of claim 2, wherein the pins 43, 44, 47, 51, and 52 of the first connector transmit audio signals; the pin 48 of the first connector transmits Speaker Output signal.

8. The printed circuit board assembly of claim 2, wherein the pins 104, 107, 108, and 111 of the first connector are used to choose different input/output module.

9. The printed circuit board assembly of claim 2, wherein the pins 28, 31, and 32 of the first connector transmit LCD controlling signals.

10. The printed circuit board assembly of claim 2, wherein the pins 5 and 118 of the first connector are used to check the connection between the first connector and the second connector.

11. A method for forming a motherboard, comprising:
attaching a CPU, memory, a north bridge chipset, a south bridge chipset, and a first connector on a central board;
attaching a power source connector, a video chipset, an audio chipset, a network card, and a second connector on a peripheral board which is separated from the central board;
connecting the first connector with the second connector to achieve communication between the central board and the peripheral board; and
transmitting signals between the central board and the peripheral board via the first and second connectors.

12. The method of claim 11, wherein the signals are one or more of DVP signals, VGA signals, SATA signals, LCD controlling signals, audio signals, speaker output signals, PCIE signals, LPC signals, PCI signals, video general input/output signals, USB signals.
